(19) United States
(12) Patent Application Publication
(10) Pub. No.: US 2026/0322077 A1
(43) Pub. Date: Oct. 15, 2026

(54) VCSEL ELEMENT, SENSOR DEVICE, ELECTRONIC DEVICE AND USER INTERFACE

(71) Applicant: ams-OSRAM International GmbH, Regensburg (DE)

(72) Inventor: Arne FLEISSNER, Regensburg (DE)

(73) Assignee: ams-OSRAM International GmbH, Regensburg (DE)

(21) Appl. No.: 19/119,189

(22) PCT Filed: Sep. 18, 2023
(86) PCT No.: PCT/EP2023/075606

§ 371 Date: Apr. 8, 2025

(30) Foreign Application Priority Data
Oct. 10, 2022 (DE) 10 2022 126 127.1

(51) Int. Cl. H01S 5/183; G01B 9/02; G01B 11/16; H01S 5/026

(52) U.S. Cl. CPC H01S 5/18394; G01B 9/02092; G01B 11/161; H01S 5/0262; H01S 5/18388

(57) ABSTRACT

A VCSEL element includes a VCSEL device attached to a substrate, which is transparent to electromagnetic radiation emitted by the VCSEL device, and a lens for deflecting electromagnetic radiation emitted by the VCSEL device. The lens is arranged on a side of the substrate (110) facing away from the VCSEL device, and a position of an aperture of the VCSEL device is displaced horizontally relative to an optical axis of the lens.

### CROSS-REFERENCE TO RELATED APPLICATIONS

The present application is a national stage entry from International Application No. PCT/EP2023/075606, filed on Sep. 18, 2023, published as International Publication No. WO 2024/078823 A1 on Apr. 18, 2024, and claims priority to German Patent Application No. 10 2022 126 127.1, filed Oct. 10, 2022, the disclosures of all of which are hereby incorporated by reference in their entireties.

### BACKGROUND

Sensor devices, for example as components of electronic devices in consumer electronics, measure a minimum deflection of the housing using optical means. The measurement principle used is, for example, so-called SMI (self-mixing interferometry). In this case, for example, electromagnetic radiation which has been emitted by a VCSEL is radiated onto the housing, reflected by the latter and superimposed with the emitted radiation. Evaluation of the superimposition signal makes it possible to ascertain information about a deflection of the housing.

In general, efforts are made to provide improved sensor devices and improved VCSEL elements.

It is an object of the present invention to provide an improved VCSEL element, an improved sensor device, an improved electronic device, and an improved user interface.

According to embodiments, the object is achieved by the subject matter of the independent claims.

Advantageous developments are defined in the dependent claims.

### SUMMARY

A VCSEL element comprises a VCSEL device attached to a substrate transparent to electromagnetic radiation emitted by the VCSEL device and a lens configured to deflect electromagnetic radiation emitted by the VCSEL device. The lens is disposed on a side of the substrate facing away from the VCSEL device. A position of an aperture of the VCSEL device is horizontally shifted from an optical axis of the lens. For example, the position of the aperture of the VCSEL device along the substrate surface is shifted from the optical axis of the lens.

According to embodiments, a sensor device comprises first and second VCSEL devices attached to a common substrate transparent to electromagnetic radiation emitted by the VCSEL device, and first and second lenses. The first lens is configured to deflect electromagnetic radiation emitted by the first VCSEL device and the second lens is configured to deflect electromagnetic radiation emitted by the second VCSEL device. The first and second lenses are disposed on a side of the substrate facing away from the VCSEL devices. A position of an aperture of the first VCSEL device is shifted from an optical axis of the first lens and a position of the aperture of the second VCSEL device is shifted from the optical axis the second lens. The first and second VCSEL devices may, for example, be disposed such that the aperture of the first VCSEL device and the aperture of the second VCSEL device are disposed at a distance smaller than the distance of the optical axes of the first and second lenses.

The lenses described herein are configured to deflect radiation emitted by an associated VCSEL device. For example, the lenses may be suitable for focusing, largely focusing, collimating or largely collimating electromagnetic radiation. Any other type of deflection or orientation of the radiation is also included.

According to further embodiments, a connecting line between the aperture of the first VCSEL device and the aperture of the second VCSEL device may be different from a connecting line between the optical axis of the first lens and the optical axis of the second lens.

The sensor device may further comprise a voltage source, wherein the first and second VCSEL devices are jointly drivable by the voltage source.

According to further embodiments, the first and second VCSEL devices may be drivable separately from each other by the voltage source.

According to embodiments, a first interference signal obtainable by coherent superposition of first radiation emitted by the first VCSEL device with a first reflected signal resulting from reflection of the first radiation at an object, and a second interference signal obtainable by coherent superposition of radiation emitted by the second VCSEL device with a second reflected signal resulting from reflection of the second radiation at the object, may be determined by reading out a voltage signal at each of the first and second VCSEL devices.

The sensor device may further comprise a first detector for detecting a first interference signal obtainable by coherent superposition of first radiation emitted by the first VCSEL device with a first reflected signal resulting from reflection of the first radiation at an object. Furthermore, the sensor device may comprise a second detector for detecting a second interference signal obtainable by coherent superposition of radiation emitted by the second VCSEL device with a second reflected signal resulting from reflection of the second radiation at the object.

According to embodiments, an electronic device comprises the above-described sensor device and a housing.

For example, the radiation emitted by the first and second VCSEL devices may be reflected at the housing, respectively.

According to embodiments, the housing may be transparent to the electromagnetic radiation emitted by the first and second VCSEL devices. The electromagnetic radiation emitted by the first and second VCSEL devices may be reflected at an object outside the housing, respectively.

For example, a user interface may comprise the above-described electronic device. A user input may be made via a local deformation of the housing.

According to further embodiments, the electromagnetic radiation emitted by the first and second VCSEL devices may be reflected at a finger, respectively. In this case, a user input may be made via a movement of the finger.

### BRIEF DESCRIPTION OF THE DRAWINGS

The accompanying drawings serve to understand example embodiments of the invention. The drawings illustrate example embodiments and together with the description serve to explain them. Further example embodiments and numerous of the intended advantages emerge directly from the following detailed description. The elements and structures shown in the drawings are not necessarily illustrated true to scale with respect to one another. Identical reference signs refer to identical or mutually corresponding elements and structures.

FIG. 1A shows a schematic cross-sectional view of a VCSEL element according to embodiments.

FIG. 1B shows a schematic cross-sectional view of a VCSEL device.

FIG. 2A shows a schematic view of a sensor device according to embodiments.

FIG. 2B shows a schematic view of elements of a sensor device according to further embodiments.

FIG. 2C shows a schematic plan view of elements of a sensor device according to further embodiments.

FIG. 2D illustrates the measurement principle of the sensor device.

FIG. 3 shows a schematic cross-sectional view of a part of an electronic device.

FIGS. 4A and 4B show cross-sectional views for illustrating the manufacture of a VCSEL device according to embodiments.

### DETAILED DESCRIPTION

In the following detailed description, reference is made to the accompanying drawings, which form a part of the disclosure and in which specific exemplary embodiments are shown for illustrative purposes. In this context, directional terminology such as “top”, “bottom”, “front”, “back”, “over”, “on”, “in front”, “behind”, “leading”, “trailing”, etc. refers to the orientation of the figures just described. Since the components of the example embodiments can be positioned in different orientations, the directional terminology serves only for explanation and is in no way restrictive.

The description of the example embodiments is not restrictive since other example embodiments also exist and structural or logical changes can be made without deviating from the scope defined by the claims. In particular, elements of example embodiments described below can be combined with elements of other example embodiments described unless the context indicates otherwise.

The terms “wafer” or “semiconductor substrate” used in the following description can comprise any semiconductor-based structure having a semiconductor surface. Wafer and structure should be understood to include doped and undoped semiconductors, epitaxial semiconductor layers, if appropriate supported by a base support, and further semiconductor structures. For example, a layer of a first semiconductor material can be grown on a growth substrate of a second semiconductor material, for example a GaAs substrate, a GaN substrate or a Si substrate, or of an insulating material, for example on a sapphire substrate.

Depending on the intended use, the semiconductor can be based on a direct or an indirect semiconductor material. Examples of semiconductor materials particularly suitable for generating electromagnetic radiation comprise, in particular, nitride semiconductor compounds by which, for example, ultraviolet, blue or longer-wave light can be generated, such as, for example, GaN, InGaN, AlN, AlGaN, AlGaInN, AlGaInBN, phosphide semiconductor compounds by which, for example, green or longer-wave light can be generated, such as, for example, GaAsP, AlGaInP, GaP, AlGaP, and further semiconductor materials such as GaAs, AlGaAs, InGaAs, AlInGaAs, SiC, ZnSe, ZnO, Ga₂ O₃, diamond, hexagonal BN and combinations of the materials mentioned. The stoichiometric ratio of the compound semiconductor materials can vary. Further examples of semiconductor materials can comprise silicon, silicon-germanium and germanium. In the context of the present description, the term “semiconductor” also includes organic semiconductor materials.

The term “substrate” generally comprises insulating, conductive or semiconductor substrates.

The terms “lateral” and “horizontal” as used in this description are intended to describe an orientation or orientation which is substantially parallel to a first surface of a substrate or semiconductor body. This can be, for example, the surface of a wafer or a chip (die).

The horizontal direction can lie, for example, in a plane perpendicular to a growth direction during the growth of layers.

The term “vertical” as used in this description is intended to describe an orientation which is substantially perpendicular to the first surface of a substrate or semiconductor body. The vertical direction can correspond, for example, to a growth direction during the growth of layers.

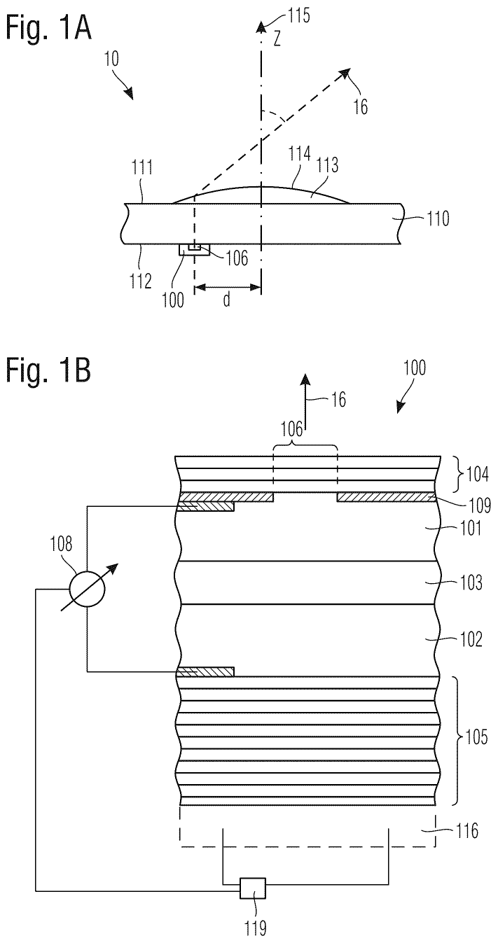

FIG. 1A shows a schematic cross-sectional view of a VCSEL element 10 according to embodiments. The VCSEL element 10 comprises a VCSEL device 100 attached to a substrate 110 transparent to electromagnetic radiation emitted by the VCSEL device 100. The VCSEL element 10 further comprises a lens 113 configured to deflect, for example focus, electromagnetic radiation emitted by the VCSEL device 100. The lens 113 is disposed on a side of the substrate 110 facing away from the VCSEL device 100. For example, the VCSEL device 100 is disposed on a second main surface 112 of the substrate, and the lens 113 is disposed on a first main surface 111 of the substrate 110. A position of an aperture of the VCSEL device 100 is shifted from an optical axis 115 of the lens. For example, the distance between the optical axis 115 and the aperture 106 of the VCSEL device 100 can be d. For example, d can be greater than 2 μm or than 5 μm. Furthermore, d can be less than 20 μm or than 15 μm. A typical value can be, for example, approximately 10 μm.

FIG. 1B shows an example of a VCSEL element 100, which can be, for example, a component of the VCSEL element shown in FIG. 1A. The VCSEL device 100 comprises a semiconductor layer stack comprising a first semiconductor layer 101 of a first conductivity type, for example p-type, and a second semiconductor layer 102 of a second conductivity type, for example n-type. An active zone 103 is disposed between the first semiconductor layer 101 and the second semiconductor layer 102.

The active zone 103 can comprise, for example, a pn-junction, a double heterostructure, a single quantum well (SQW) structure or a multi quantum well (MQW) structure for generating radiation. The term “quantum well structure” here does not have any significance with regard to the dimensionality of the quantization. It thus comprises, inter alia, quantum wells, quantum wires and quantum dots and any combination of these layers.

A first resonator mirror 104 is disposed adjacent to the first semiconductor layer 101. A second resonator mirror 105 is disposed adjacent to the second semiconductor layer 102. For example, the first and the second resonator mirror 104, 105 can now be formed as a dielectric mirror layer and may comprise a multiplicity of dielectric layers having different refractive indices, respectively.

In general, the term “dielectric mirror layer” comprises any arrangement which reflects incident electromagnetic radiation to a large degree (for example >90%) and is nonconductive. For example, a dielectric mirror layer can be formed by a sequence of very thin dielectric layers having different refractive indices, respectively. For example, the layers can alternately have a high refractive index (n>n₀) and a low refractive index (n<n₀) and be formed as a Bragg reflector. For example, the layer thickness can be λ/4, where λ indicates the wavelength of the light to be reflected in the respective medium. The layer seen from the incident light can have a greater layer thickness, for example 3λ/4. On account of the small layer thickness and the difference in the respective refractive indices, the dielectric mirror layer provides a high reflectivity and at the same time is nonconductive. A dielectric mirror layer can comprise, for example, 2 to 50 dielectric layers. A typical layer thickness of the individual layers can be approximately 30 to 90 nm, for example approximately 50 nm. The layer stack can further comprise one or two or more layers which are thicker than approximately 180 nm, for example thicker than 200 nm.

According to further configurations, the layers of the resonator mirrors 104 and 105 can also comprise semiconductor layers.

When a voltage is applied between the first semiconductor layer and the second semiconductor layer 102, electrical radiation 16 is emitted. In this case, an optical resonator forms in the vertical direction, i.e. perpendicular to the surface of the individual layers. An aperture 106 can be formed, for example, in a blocking layer 109, i.e. in a layer impermeable to the electromagnetic radiation. The electromagnetic radiation is emitted via the aperture 106. For example, a diameter of the aperture 106 can be approximately greater than 2 μm. For example, the diameter of the aperture 106 can be less than 8 μm. For example, the diameter of the aperture 106 can be approximately 4 μm. Depending on the configuration, the blocking layer 109 can be disposed on the side of the first resonator mirror 104 facing or facing away from the first semiconductor layer 101. According to configurations, the term “aperture” denotes an emission region of a VCSEL device.

For example, an electrical voltage can be applied by a voltage source 108. For example, terminals of the voltage source 108 can be connected to the first semiconductor layer 101 and the second semiconductor layer 102 via suitable contact regions. In addition, the VCSEL device 100 can comprise a detector 116, for example a photodiode, which can be monolithically integrated with the VCSEL device 100, for example. The detector 116 can detect, for example, an interference signal generated by so-called SMI, in which the emitted radiation is coherently superimposed with reflected radiation. According to further embodiments, a signal generated by SMI can be detected by the VCSEL device 100 itself, for example by determining the change in a voltage signal, for example by the voltage source 108 or a component of the voltage source.

The detected signal can be evaluated, for example, by an evaluation circuit 119. The evaluation circuit 119 can be connected to the voltage source 108. In particular, information about a level of the applied voltage can be passed on to the evaluation circuit.

By virtue of the fact that, as shown in FIG. 1A, the position of the aperture 106 of the VCSEL device 100 is shifted from the optical axis 115 of the lens 113, emitted beams 16 at the boundary surface 114 between the lens 113 and the surrounding air are refracted toward the optical axis. Correspondingly, it is possible to deflect the emitted radiation 16.

With the VCSEL element 10 shown, it is possible, for example, to arrange a multiplicity of VCSEL elements 10 spatially close together and at the same time to generate the generated beams 16 with an increased spatial distance.

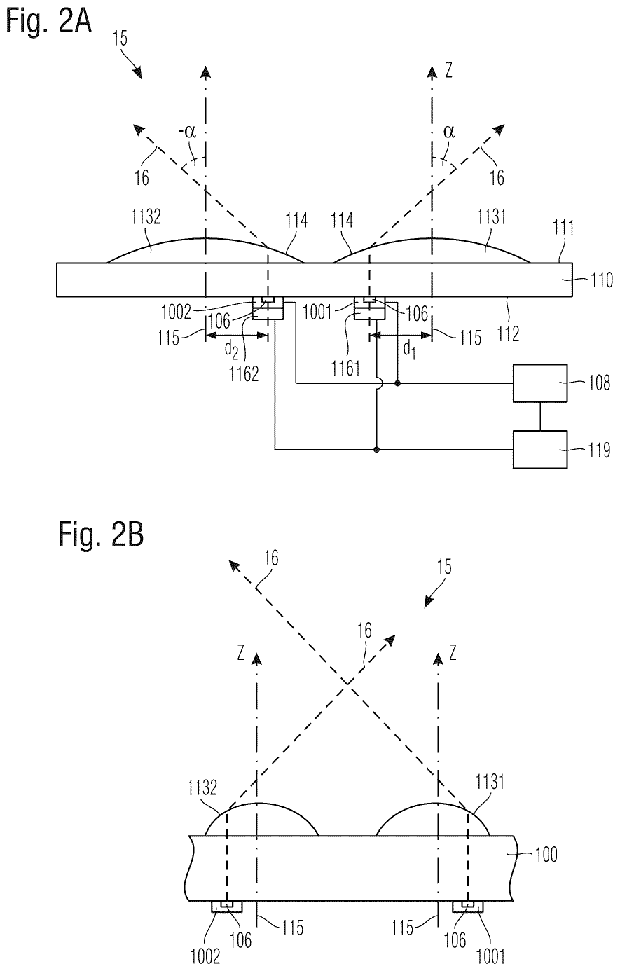

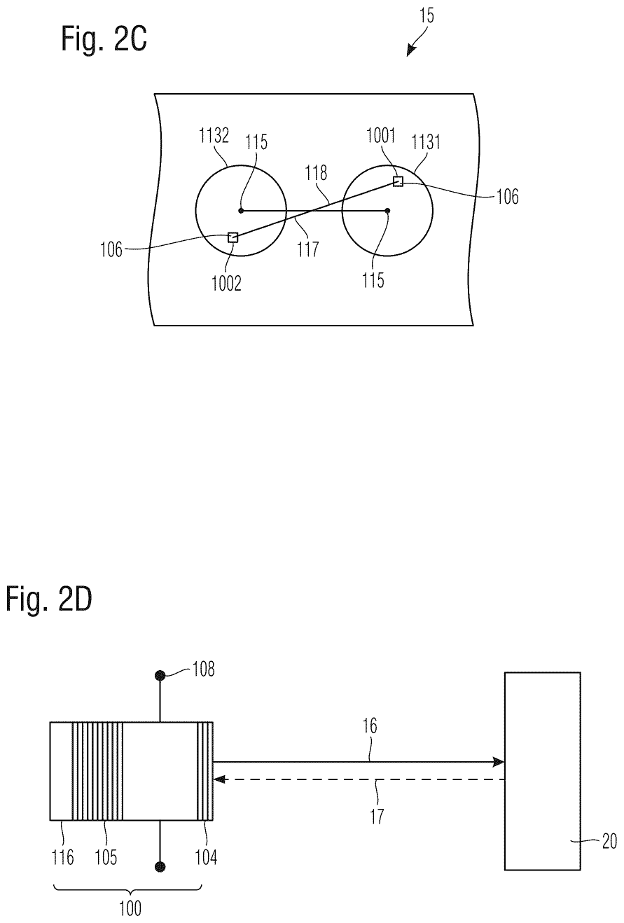

FIG. 2A shows a sensor device 15 according to embodiments. The sensor device 15 shown in FIG. 2A comprises a first VCSEL device 1001 and a second VCSEL device 1002. The first and second VCSEL devices 1001, 1002 are attached to a common substrate 110. The common substrate 110 is transparent to electromagnetic radiation 16 emitted by the VCSEL devices 1001, 1002.

The sensor device 15 further comprises a first lens 1131 and a second lens 1132. The first lens 1131 is configured to deflect, for example focus, electromagnetic radiation emitted by the first VCSEL device 101. The second lens 1132 is configured to deflect, for example focus, electromagnetic radiation emitted by the second VCSEL device 1002. The first and second lenses 1131, 1132 are disposed on a side of the substrate 110 facing away from the VCSEL devices 1001, 1002. A position of an aperture of the first VCSEL device 1001 is shifted from the optical axis 115 of the first lens 1131 by a distance d₁. Furthermore, a position of the aperture of the second VCSEL device 1002 is shifted from the optical axis 115 of the second lens 1132 by a distance d₂. For example, the distances d₁ and d₂ can be equal to one another. According to further embodiments, the distances d₁ and d₂ can also be different from one another.

For example, the first VCSEL device 1001 and the second VCSEL device 1002 are disposed such that the aperture of the first VCSEL device 1001 and the aperture of the second VCSEL device 1002 are disposed at a distance smaller than the distance of the optical axes of the first and second lenses. For example, both the first VCSEL device 1001 and the second VCSEL device 1002 face one another, i.e. the first VCSEL device 1001 or the aperture of the first VCSEL device 1001 is disposed on the side of the optical axis 115 of the associated first lens 1131 facing the second lens 1132. Furthermore, the second VCSEL device 1002 or the aperture of the second VCSEL device 1002 is disposed on the side of the optical axis 115 of the second lens 1132 facing the first lens 1131.

In this way, it is possible to dispose individual VCSEL devices at a small distance, while the electromagnetic radiation 16 is emitted at a greater distance, respectively.

Similarly as shown in FIG. 1B, according to embodiments, the first VCSEL device 1001 also comprises a first detector 1161 here. Furthermore, the second VCSEL device 1002 can comprise a second detector 1162. The sensor device 15 can further comprise a voltage source 108 for operating the first VCSEL device 1001 and the second VCSEL device 1002. For example, the first VCSEL device 1001 can be operated independently of the second VCSEL device 1002 by the voltage source 108. According to further embodiments, however, both VCSEL devices can also be operated jointly. The evaluation circuit 119 can be connected, for example, to the voltage source 108 and further be suitable for evaluating signals of the detectors 1161, 1162.

According to embodiments, a signal generated by SMI can also be detected in each case by the VCSEL device 1001, 1002 and read out via a voltage signal. The evaluation circuit 119 can be connected, for example, to the voltage source 108 and further be suitable for reading out the determined voltage signals.

In an optical sensor device which detects, for example, a local deformation of a housing or the movement of a finger and which is based on self-mixing interference, preferably at least two measuring points are used in order to increase the accuracy and reliability of the measurement. By virtue of the fact that, as shown in FIG. 2A, the first and second VCSEL devices 1001 and 1002 are disposed in the described way, it is possible to dispose the individual VCSEL devices at a short distance and to provide a minimum distance of the corresponding measuring points, even if the reflective housing or the finger has a small distance, for example of less than approximately 10 cm. Furthermore, the first VCSEL device 1001 and the second VCSEL device 1002 are realized in a common VCSEL chip by the sensor device shown in FIG. 2A. In this way, a sensor device having a small size can be realized as a VCSEL chip.

As further shown in FIG. 2A, depending on the curvature of the respective lenses 113, the distance d between the aperture 106 and the optical axis 115 of the lens can be selected such that the angle α between the emission direction of the emitted laser beam 16 and the optical axis 115 is greater than 20°, for example greater than 30°, for example approximately 35°.

The distance between the apertures of the first VCSEL device 1001 and the second VCSEL device 1002 can be, for example, less than 50 μm. The beam 16 emitted by the second VCSEL device 1002 can be deflected, for example, in a direction which deviates by −α from the optical axis 115 of the second lens 1132. The beam 16 emitted by the second VCSEL device 1001 can be, for example, counter to the beam 16 emitted by the VCSEL device 1001.

In FIG. 2A, the VCSEL devices 1001 and 1002 are each illustrated as separate elements. According to further embodiments, they can also comprise common layers and be electrically separated from each other.

FIG. 2B shows a further example of an arrangement of VCSEL devices 1001, 1002 in a sensor device 15 according to further embodiments. The sensor device 15 shown in FIG. 2B can comprise, for example, components similar to the sensor device 15 shown in FIG. 2A. As shown in FIG. 2B, the VCSEL devices 1001, 1002 can also be disposed such that a distance between the apertures 106 is greater than the distance between the optical axes 115 of the associated lenses 1131, 1132.

FIG. 2C shows a schematic plan view of elements of a sensor device 15 according to embodiments. As shown in FIG. 2C, for example, a connecting line 118 between the aperture 106 of the first VCSEL device 1001 and the aperture 106 of the second VCSEL device 1002 may be different from a connecting line 117 between the optical axis 115 of the first lens 1131 and the optical axis 115 of the second lens 1132. For example, the two connecting lines can intersect one another or be displaced parallel to one another. According to further configurations, the distance between the apertures 106 of the first and second VCSEL devices 1001, 1002 may be different from or equal to the distance between the optical axes 115 of the first and second lenses 1131, 1132.

FIG. 2D illustrates a measurement arrangement using the VCSEL arrangement shown in FIG. 2A. A beam 16 is emitted by a VCSEL 100. This is reflected at an object 20, so that the reflected beam 17 is generated. The detector 116 is suitable for detecting a superimposition signal from the emitted radiation 16 and the reflected radiation 17. The VCSEL device 100 shown in FIG. 2D comprises components similar to the VCSEL device shown in FIG. 1B, so that a detailed description is omitted.

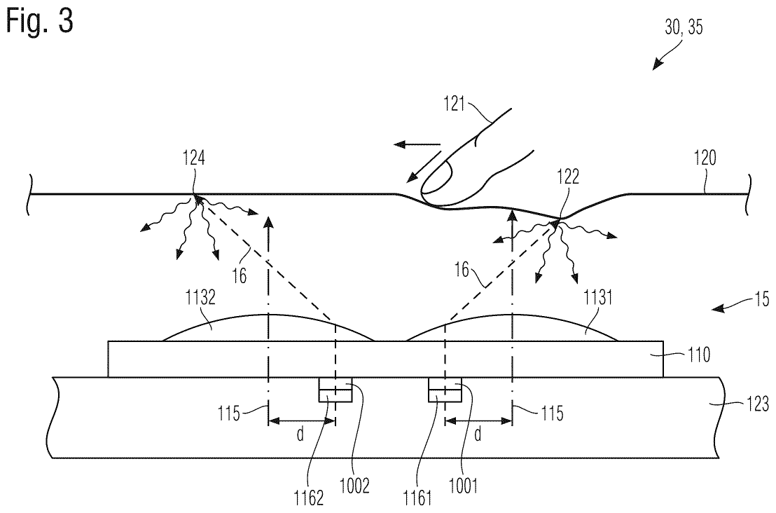

FIG. 3 shows a part of an electronic device 30 or the user interface 35. For example, the sensor device 15 described with reference to FIG. 2A is attached to a suitable carrier 123. The VCSEL devices 1001, 1002 can be disposed between the carrier 123 and the substrate 110. The VCSEL devices 1001, 1002 can be formed, as indicated in FIG. 3, as separate elements or may comprise common layers, respectively.

A housing 120 is disposed over the sensor device 15. For example, the sensor device 15 can be disposed in an electronic device 30, and the housing 120 simultaneously forms the housing of the electronic device 120. As is further illustrated in FIG. 3, a finger 121 moves in the direction of the arrow and in the process exerts a pressure in the direction of the sensor device 15. As a result, a reduction in the distance between the housing 120 and the sensor device 15 takes place. The position of the first measuring point 122 is defined by the position of the point of intersection of the radiation 16 emitted by the first VCSEL device 1001 with the housing 120. Furthermore, the position of the second measuring point 124 is defined by the position of the point of intersection of the radiation 16 emitted by the second VCSEL device 1002 with the housing 120.

Usually, the first measuring point 122 and the second measuring point 124 can have a distance of at least 1 mm, for example 2 mm. By virtue of the fact that, as described above with reference to FIG. 2A, the apertures of the in each case first VCSEL device 1001 and the second VCSEL device 1002 are displaced from the optical axis of the lens 113, this minimum distance can be maintained even if the first and second VCSEL devices 1001, 1002 are disposed on a common chip and are thus embodied in a particularly space-saving manner.

For example, the movement of the finger, i.e. distance and speed of the finger, can be determined by modulating the output power of the VCSELs or the forward voltage of the VCSELs and evaluating the signals detected by the detectors 1161, 1162. These concepts are known and have been described in detail under the term “FMCW-LIDAR” (frequency modulated continuous wave LIDAR).

According to embodiments, as described above, the VCSEL devices 1001, 1002 themselves can detect a generated SMI signal by changing a voltage signal. In this case, no separate detectors 1161, 1162 are required.

The arrangement shown in FIG. 3 may be part of an electronic device, for example a portable terminal, a smartphone, a camera or, for example, headphones.

According to further embodiments, the arrangement shown in FIG. 3 also provides a user interface 35. For example, in the case of cordless headphones or earbuds, commands can be input by pressing the housing. In this case, a user input can be made by moving the finger in order, for example, to regulate the volume or to bring about some other control.

According to embodiments, the housing 120 may be opaque. In this case, the deflection of the housing 120 is measured and leads to the generation of the desired signals.

According to further embodiments, the housing 120 may also be transparent. In this case, for example, the emitted electromagnetic radiation 16 may be reflected at the finger 121 and thus lead to the generation of the desired signals. In this case, the first measuring point 122 may correspond to the point of intersection of the radiation 16 emitted by the first VCSEL device 1001 with the finger. The second measuring point 124 may correspond to the point of intersection of the radiation 16 emitted by the second VCSEL device 1002 with the finger.

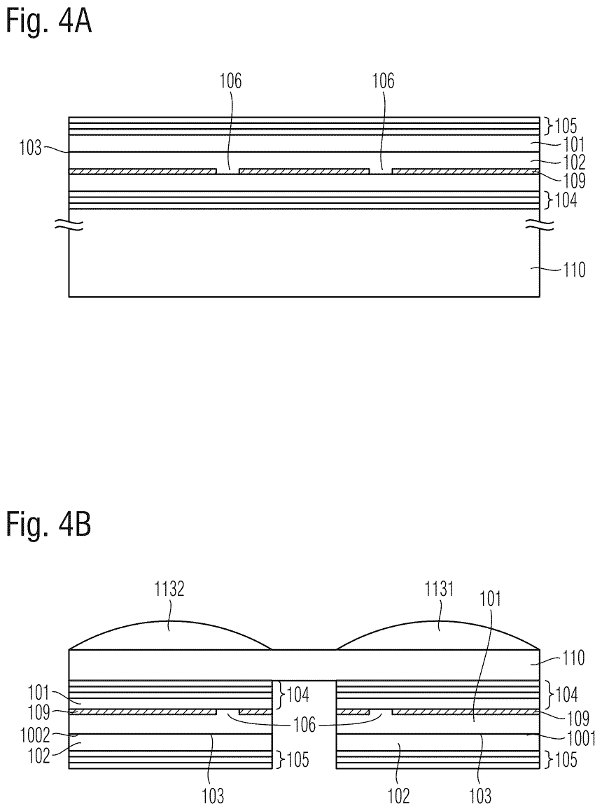

FIGS. 4A to 4B illustrate an example of a method for manufacturing the sensor device or an arrangement of VCSEL elements according to embodiments.

Firstly, as indicated in FIG. 4A, layers for forming the respective VCSEL devices 1001, 1002 at the wafer level are formed on a substrate 110 which acts as a growth substrate and is transparent to the electromagnetic radiation to be emitted by the VCSEL device 100. The associated methods are generally known, so that a detailed description is omitted.

The substrate 110 is thinned and then etched to form the lenses 113. Furthermore, the semiconductor layer stacks belonging to the individual VCSEL devices 1001, 1002 are each separated from each other and electrically insulated, for example by etching a mesa. This is illustrated in FIG. 4B. The etching of the lenses 113 is carried out in such a way that the optical axis 115 of the individual lenses is shifted from the aperture 106 of the individual laser devices 100, as has been described above.

Although specific embodiments have been illustrated and described herein, persons skilled in the art will recognize that the specific embodiments shown and described can be replaced by a multiplicity of alternative and/or equivalent configurations without departing from the scope of protection of the invention. The application is intended to cover any adaptations or variations of the specific embodiments discussed herein. Therefore, the invention is restricted only by the claims and the equivalents thereof.

1. An electronic device comprising a sensor device and a housing, the sensor device comprising:
a first and a second VCSEL device formed in a common chip and attached to a common substrate transparent to electromagnetic radiation emitted by the first and the second VCSEL device, wherein the electromagnetic radiation is emitted via an aperture of the first or the second VCSEL device, respectively; and
a first and a second lens, the first lens configured to deflect electromagnetic radiation emitted from the first VCSEL device and the second lens configured to deflect electromagnetic radiation emitted by the second VCSEL device,
wherein the first and second lenses are disposed on a side of the substrate facing away from the VCSEL devices,
wherein a position of an aperture of the first VCSEL device is shifted from an optical axis of the first lens and a position of the aperture of the second VCSEL device is shifted from the optical axis of the second lens, wherein the radiation emitted by the first and second VCSEL devices is reflected at the housing or an object located on the housing, respectively.

2. The electronic device according to claim 1, wherein
the first and second VCSEL devices are disposed such that a distance between the aperture of the first VCSEL device and the aperture of the second VCSEL device is different from a distance of the optical axes of the first and second lenses.

3. The electronic device according to claim 1, wherein a connecting line between the aperture of the first VCSEL device and the aperture of the second VCSEL device is different from a connecting line between the optical axis of the first lens and the optical axis of the second lens.

4. The electronic device according to claim 2, wherein the distance between the aperture of the first VCSEL device and the aperture of the second VCSEL device is smaller than the distance of the optical axes of the first and second lenses.

5. The electronic device according to claim 1, further comprising a first detector for detecting a first interference signal obtainable by coherent superposition of first radiation emitted by the first VCSEL device with a first reflected signal resulting from reflection of the first radiation at an object, and a second detector for detecting a second interference signal obtainable by coherent superposition of radiation emitted by the second VCSEL device with a second reflected signal resulting from reflection of the second radiation at the object.

6. The electronic device according to claim 1, further comprising a voltage source, wherein the first and second VCSEL devices are jointly drivable by the voltage source.

7. The electronic device according claim 1, further comprising a voltage source, wherein the first and second VCSEL devices are drivable separately from each other by the voltage source.

8. The electronic device according to claim 6, wherein a first interference signal obtainable by coherent superposition of first radiation emitted by the first VCSEL device with a first reflected signal resulting from reflection of the first radiation at an object, and a second interference signal obtainable by coherent superposition of radiation emitted by the second VCSEL device with a second reflected signal resulting from reflection of the second radiation at the object, is configured to be determined by reading out a voltage signal at each of the first and second VCSEL devices.

9. A user interface comprising the electronic device according to claim 1, wherein a user input is made via a local deformation of the housing.

10. A user interface comprising the electronic device according to claim 1, wherein the electromagnetic radiation emitted by the first and second VCSEL devices is reflected at a finger, respectively, and a user input is made via a movement of the finger.
